(19) United States
(12) Patent Application Publication
(10) Pub. No.: US 2026/0136691 A1
(43) Pub. Date: May 14, 2026

(54) IMAGE SENSOR AND IMAGING APPARATUS

(71) Applicant: CANON KABUSHIKI KAISHA, Tokyo (JP)

(72) Inventors: YUKI YOSHIMURA, Tokyo (JP); KOICHI FUKUDA, Tokyo (JP); KOHEI OKAMOTO, Kanagawa (JP); SHUNICHI WAKASHIMA, Tokyo (JP)

(21) Appl. No.: 19/373,943

(22) Filed: Oct. 30, 2025

(30) Foreign Application Priority Data
Nov. 13, 2024 (JP) 2024-198225

(51) Int. Cl. H10F 39/00; H10F 30/223; H10F 39/18

(52) U.S. Cl. CPC H10F 39/8027; H10F 39/8063; H10F 30/223; H10F 39/182

(57) ABSTRACT

An image sensor includes pixels that each have a photoelectric conversion region divided into a plurality of regions in a first direction and are arrayed in a 2-dimensional form. A longitudinal direction of the image sensor matches the first direction. In the first direction, a change amount of a deviation amount between an optical axis of a microlens included in the pixel and a center of a divided region of the photoelectric conversion region, relative to a change in an image height that is a distance from a center of the image sensor is a first change amount on a center side relative to a first predetermined image height and is a second change amount on an outer side relative to the first predetermined image height. The first change amount is greater than the second change amount.

### BACKGROUND

### Field of the Technology

The present disclosure relates to an image sensor and an imaging apparatus.

### Description of the Related Art

One type of focus detection method performed by an imaging apparatus is an imaging-plane phase difference method of performing focus detection by a phase difference scheme with focus detection pixels formed in an image sensor. Japanese Patent Application Laid-open No. 2004-228645 discloses a scheme in which because an exit pupil distance of an imaging lens changes with an image height between a side where an imaging lens is disposed (positive direction) and a side where no imaging lens is disposed (negative direction), an optical axis of a microlens is changed in accordance with the image height to follow this change.

However, according to the technique of the related art, a case where an image sensor and an imaging lens having a large change in an exit pupil distance in accordance with an image height are used in combination has not been assumed, and there is concern of accuracy of focus detection deteriorating at any image height.

### SUMMARY

An object of the present disclosure is to provide an image sensor that performs focus detection with high accuracy at any image height even when the image sensor is used in combination with an imaging lens having a large change in an exit pupil distance in accordance with an image height.

To solve the above problem, according to an aspect of the present disclosure, an image sensor includes pixels that each have a photoelectric conversion region divided into a plurality of regions in a first direction and are arrayed in a 2-dimensional form. A longitudinal direction of the image sensor matches the first direction. In the first direction, a change amount of a deviation amount between an optical axis of a microlens included in the pixel and a center of a divided region of the photoelectric conversion region, relative to a change in an image height that is a distance from a center of the image sensor is a first change amount on a center side relative to a first predetermined image height and is a second change amount on an outer side relative to the first predetermined image height. The first change amount is greater than the second change amount.

Features of the present disclosure will become apparent from the following description of embodiments with reference to the attached drawings. The following description of embodiments is described by way of example.

### BRIEF DESCRIPTION OF THE DRAWINGS

FIG. 1 is a diagram illustrating an overall configuration of a camera.

FIG. 2 is a diagram illustrating array of pixels in an image sensor.

FIG. 3A is a plan view when the pixel is viewed from a light reception surface side of the image sensor and FIG. 3B is a sectional view taken along the line a-a when the pixel illustrated in FIG. 3A is viewed from the-y side.

FIG. 4 is a sectional view taken along the line a-a when the pixel illustrated in FIG. 3A is viewed on the +y side and a diagram illustrating an exit pupil plane of an image forming optical system.

FIG. 5 is a schematic diagram illustrating a relationship between the pixels of the image sensor and first and second pupil partial regions.

FIGS. 6A and 6B are diagrams illustrating a light intensity distribution when light is incident on a microlens formed in a pixel.

FIG. 7 is a diagram illustrating a light reception rate distribution (pupil intensity distribution) that depends on an incidence angle of light.

FIG. 8 is a diagram illustrating a relationship between an entrance pupil of the image sensor and the exit pupil of the image forming optical system.

FIG. 9 is a diagram illustrating a relationship between an image height and an exit pupil angle in a specific lens.

FIG. 10 is a diagram illustrating a relationship between an image height and a deviation amount when an imaging lens having the relationship between the image height and the exit pupil angle illustrated in FIG. 9 is used and when an incidence pupil distance is the same as an exit pupil distance.

FIG. 11 is a diagram illustrating a relationship between an image height of the image sensor and a change amount of the deviation amount relative to any image height.

FIGS. 12A to 12C are diagrams illustrating a relationship of a change amount of the deviation amount relative to an image height for each pixel of the image sensor.

FIG. 13A is a plan view when the pixel is viewed from a light reception plane side of an image sensor and FIG. 13B is a sectional view taken along the line a-a when the pixel illustrated in FIG. 13A is viewed from on the-y side according to a modified example.

FIG. 14 is a diagram illustrating a relationship between an entrance pupil of the image sensor and an exit pupil of an image forming optical system.

FIG. 15 is a diagram illustrating a relationship between an image height of the image sensor and a change amount of the deviation amount relative to any image height.

FIGS. 16A to 16C are diagrams illustrating a relationship of a change amount of the deviation amount relative to an image height in each pixel of the image sensor.

### DESCRIPTION OF THE EMBODIMENTS

Hereinafter, embodiments of the present disclosure will be described with reference to the drawings.

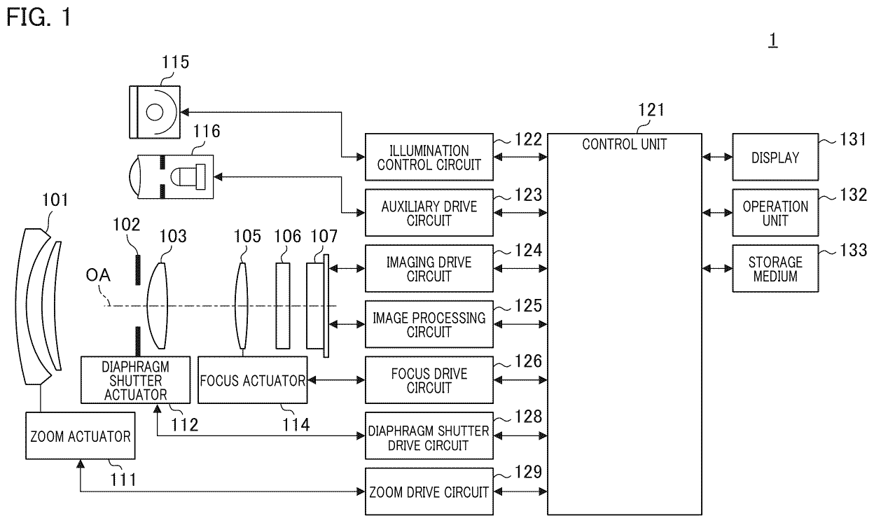

FIG. 1 is a diagram illustrating an overall configuration of a camera 1. The camera 1 that is an example of an imaging apparatus includes a first lens group 101, a shutter 102 also serving as a diaphragm, a second lens group 103, a third lens group 105, an optical filter 106, and an image sensor 107. The camera 1 further includes a zoom actuator 111, a diaphragm shutter actuator 112, a focus actuator 114, an illumination device 115, an auxiliary light-emitting unit 116, a control unit 121, an illumination control circuit 122, an auxiliary drive circuit 123, and an imaging drive circuit 124. The camera 1 further includes an image processing circuit 125, a focus drive circuit 126, a diaphragm shutter drive circuit 128, a zoom drive circuit 129, a display 131, an operation unit 132, and a storage medium 133.

The first lens group 101 is disposed at a distal end of an image forming optical system and is held to be movable forward and backward in an optical axis direction. The shutter 102 also serving as the diaphragm adjusts an amount of light during imaging by adjusting an aperture diameter. The shutter 102 also serving as the diaphragm functions as a shutter for exposure time adjustment during capturing of a still image. The second lens group 103 integrally moves forward or backward with the shutter 102 also serving as the diaphragm in the optical axis direction and implements a variable magnification action (zoom function) in coordination with a forward or backward operation of the first lens group 101. The third lens group 105 (focus lens) moves forward or backward in the optical axis direction to adjust focus. The optical filter 106 is an optical element that reduces false color or moire of a captured image. The image sensor 107 includes a 2-dimensional CMOS photosensor and peripheral circuits and is disposed on an image forming plane of an image forming optical system. The first lens group 101, the second lens group 103, the third lens group 105 are examples of the image forming optical system. The first lens group 101, the second lens group 103, the third lens group 105 can also be ascertained as an imaging lens.

The zoom actuator 111 drives the first lens group 101 or the second lens group 103 forward or backward in the optical axis direction by rotating a cam tube (not illustrated) to implement a variable magnification operation. The diaphragm shutter actuator 112 controls an aperture diameter of the shutter 102 also serving as the diaphragm to adjust an amount of imaging light and performs exposure time control during capturing of a still image. The focus actuator 114 drives the third lens group 105 forward or backward in the optical axis direction to implement focus adjustment. The illumination device 115 is used as an illumination during imaging. As the illumination device 115, a flash illumination device using a xenon tube is appropriately used, but an illumination device including an LED that continuously emits light may be used. The auxiliary light-emitting unit 116 projects a predetermined image of a mask having a predetermined aperture pattern to a subject through a projection lens to improve a focus detection capability for a dark subject or a low-contrast subject.

The control unit 121 controls the entire camera 1. The control unit 121 includes an arithmetic unit, a ROM, a RAM, an A/D converter, a D/A converter, and a communication interface circuit. The control unit 121 drives various circuits included in the camera 1 and performs a series of operations such as AF, imaging, image processing, and recording based on predetermined programs stored in the ROM. The illumination control circuit 122 controls lighting of the illumination device 115 in synchronization with an imaging operation. The auxiliary drive circuit 123 controls lighting of the auxiliary light-emitting unit 116 in synchronization with a focus detection operation. The imaging drive circuit 124 that is an example of a processing unit controls an imaging operation of the image sensor 107, performs A/D conversion on an acquired image signal, and transmits the image signal to the control unit 121. The image processing circuit 125 that is an example of the processing unit performs a process such as γ conversion, color interpolation, or JPEG compression on an image acquired by the image sensor 107. The focus drive circuit 126 drives and controls the focus actuator 114 based on a focus detection result and drives the third lens group 105 forward or backward in the optical axis direction to perform focus adjustment. The diaphragm shutter drive circuit 128 drives and controls the diaphragm shutter actuator 112 to control an aperture of the shutter 102 also serving as the diaphragm. The zoom drive circuit 129 drives the zoom actuator 111 in response to a zoom operation of a user.

The display 131 displays information regarding an imaging mode of the camera, a preview image before imaging, a confirmation image after imaging, a focus state display image during focus detection, and the like. As the display 131, there is an LCD or the like. The operation unit 132 accepts an operation of the camera 1 by the user. The operation unit 132 includes a power switch, a release (imaging trigger) switch, a zoom operations switch, and an imaging mode selection switch. The storage medium 133 records captured images. The storage medium 133 may be detachably mounted on the camera 1.

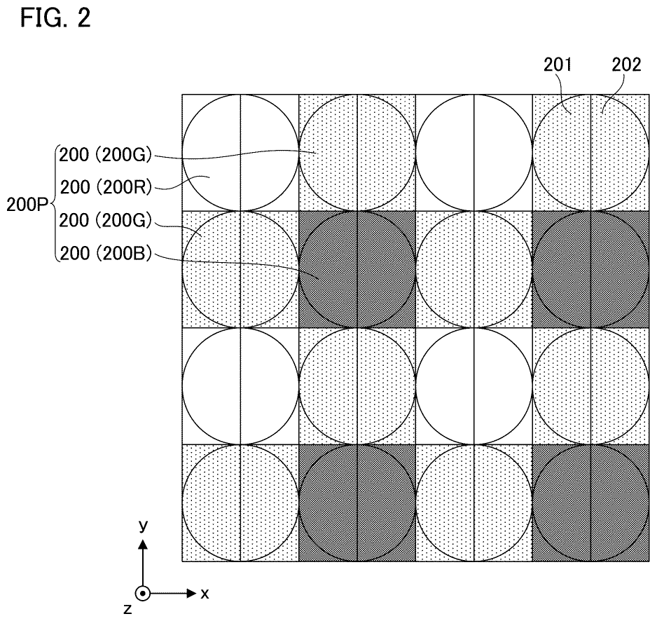

FIG. 2 is a diagram illustrating array of pixels 200 in the image sensor 107. In FIG. 2, right and left directions in the drawing are also referred to as the x direction, up and down directions in the drawing are referred to as the y direction, and front and back directions in the drawing are also referred to as the z direction.

As illustrated in FIG. 2, pixel groups 200P are provided in the image sensor 107. Each pixel group 200P includes four pixels 200. The four pixels 200 include one pixel 200R that has red spectral sensitivity, two pixels 200G that have green spectral sensitivity, and one pixel 200B that has blue spectral sensitivity. More specifically, in the pixel group 200P, the pixel 200R that has red spectral sensitivity is arrayed at the top left, the pixels 200G that have green spectral sensitivity are arrayed at the top right and bottom left, and the pixel 200B that has blue spectral sensitivity is arrayed at the bottom right. In each pixel 200, a first focus detection pixel 201 and a second focus detection pixel 202 are arranged in the x direction. When it is not necessary to distinguish the first focus detection pixel 201 and the second focus detection pixel 202 from each other in description, the first focus detection pixel 201 and the second focus detection pixel 202 are simply referred to as the focus detection pixels.

In the illustrated example, the pixel groups 200P are arrayed in two rows×two columns. In the illustrated example, the pixels 200 are arrayed in four rows×four columns. Further, in the illustrated example, the focus detection pixels are arrayed in four rows×eight columns. In the embodiment, many pixel groups 200P in the two rows×two columns illustrated in FIG. 2 are arrayed on a surface, so that a captured image (focus detection signal) is acquired. In the image sensor 107 according to the embodiment, it is assumed that a horizontal size H is 36 mm, a vertical size V is 24 mm, a pixel pitch P is 4.8 μm, and the number of pixels N is horizontal 7500 columns×vertical 5000 rows=37.5 million pixels. In the image sensor 107, it is assumed that a pitch PAF of the focus detection pixel in the column direction is 2.4 μm and the number of focus detection pixels NAF is horizontal 15000 columns×vertical 75000 rows=75 million pixels.

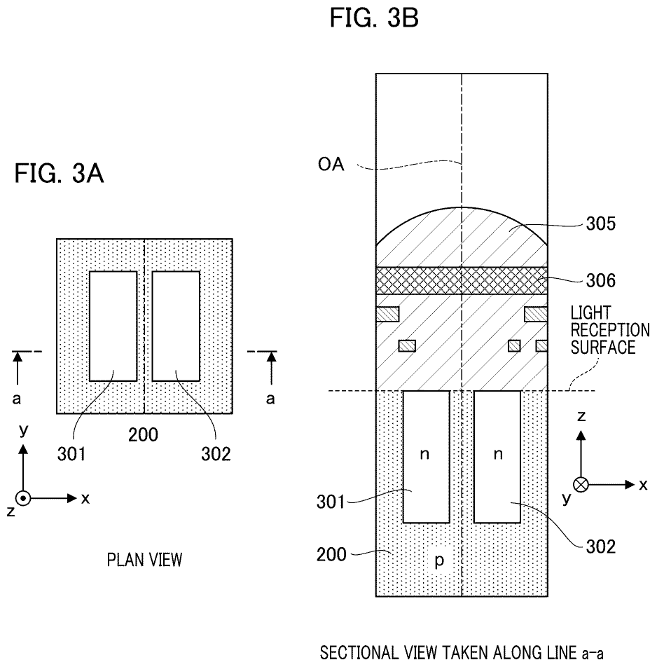

FIG. 3A is a plan view when the pixel 200 is viewed from a light reception surface side (+z side) of the image sensor 107 and FIG. 3B is a sectional view taken along the line a-a when the pixel 200 illustrated in FIG. 3A is viewed from the-y side.

As illustrated in FIGS. 3A and 3B, a microlens 305 that condenses incident light toward a light reception side of each pixel is provided in the pixel 200. In the pixel 200, photoelectric conversion units 301 and 302 divided into NH divisions (two divisions) in the x direction and NV division (one division) in the y direction are formed. The photoelectric conversion unit 301 corresponds to the first focus detection pixel 201 and the photoelectric conversion unit 302 corresponds to the second focus detection pixel 202. The photoelectric conversion units 301 and 302 may be pin structure photodiodes in which an intrinsic layer is interposed between a p-type layer and an n-type layer. The photoelectric conversion units 301 and 302 may be pn junction photodiodes in which an intrinsic layer is omitted. In the pixel 200, a microlens 305 and a color filter 306 are formed. Spectral transmittance of the color filer 306 may change in accordance with a focus detection pixel or the color filter 306 may be omitted. When it is not necessary to distinguish the photoelectric conversion units 301 and 302 from each other, the photoelectric conversion units 301 and 302 may be simply referred to as the photoelectric conversion units.

Light incident on the pixel 200 is condensed by the microlens 305, is spectrally separated by the color filter 306, and then is received by the photoelectric conversion units 301 and 302. In the photoelectric conversion units 301 and 302, electrons and holes are generated in pairs in accordance with an amount of received light and are separated in a depletion layer. Thereafter, negatively charged electrons are stored in n-type layers (not illustrated) while the holes are discharged to the outside of the image sensor 107 through p-type layers connected to a constant voltage (not illustrated). The electrons stored in the n-type layers (not illustrated) of the photoelectric conversion units 301 and 302 are transferred to an electrostatic capacity (FD) unit via a transfer gate to converted into an electric signal and output. A focal position of the microlens 305 changes depending on a shape (curvature or the like) of the microlens, a material (a refractive index or the like), and a positional relationship with a corresponding photoelectric conversion unit. By setting such parameters, it is possible to set a focal position of the microlens 305.

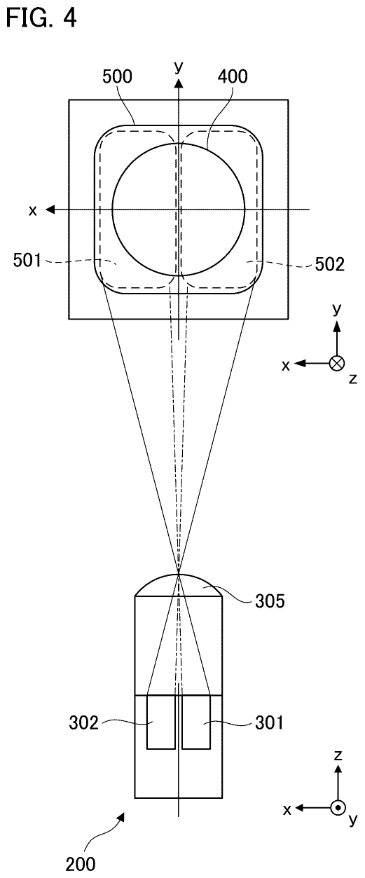

FIG. 4 is a sectional view taken along the line a-a when the pixel 200 illustrated in FIG. 3A is viewed on the +y side and a diagram illustrating an exit pupil plane of an image forming optical system.

A pupil region 500 illustrated in FIG. 4 is a pupil region where all the pixels 200 can receive light when the photoelectric conversion units 301 and 302 (the first focus detection pixel 201 and the second focus detection pixel 202) are both combined. In the pupil region 500, there are a first pupil partial region 501 and a second pupil partial region 502. The first pupil partial region 501 has a substantially conjugate relationship with the light reception surface of the photoelectric conversion unit 301 of which the center of gravity is eccentric in the −x direction by the microlens 305, and thus serves as a pupil region where the first focal detection pixel 201 can receive light. The first pupil partial region 501 overlaps on the +X side relative to the center of an aperture 400 of the shutter 102 also serving as the diaphragm because the center of gravity is eccentric in the +x side on a pupil plane. The second pupil partial region 502 has a substantially conjugate relationship with the light reception surface of the photoelectric conversion unit 302 of which the center of gravity is eccentric in the +x direction by the microlens 305, and thus serves as a pupil region where the second focal detection pixel 202 can receive light. The second pupil partial region 502 overlaps on the −x side relative to the center of the aperture 400 because the center of gravity is eccentric in the −x side on a pupil plane.

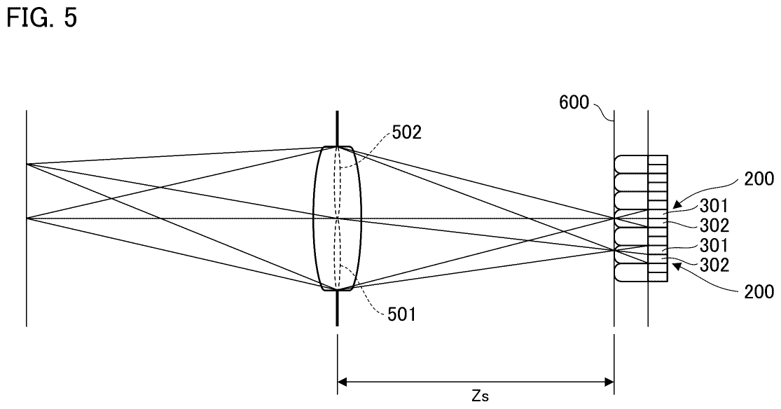

FIG. 5 is a schematic diagram illustrating a relationship between the pixels 200 of the image sensor 107, and the first pupil partial region 501 and the second pupil partial region 502. At an incidence pupil distance Zs of the image sensor 107, the first pupil partial region 501 corresponding to a light reception region of the first focal detection pixel 201 is substantially matched for each pixel 200 on a surface 600 of the image sensor 107. Similarly, at an incidence pupil distance Zs of the image sensor 107, the second pupil partial region 502 corresponding to a light reception region of the second focal detection pixel 202 is substantially matched for each pixel 200 on the surface 600 of the image sensor 107. That is, at an incidence pupil distance Zs of the image sensor 107, a pupil division position between the first pupil partial region 501 and the second pupil partial region 502 is substantially matched. A pair of light fluxes passing through the first pupil partial region 501 and the second pupil partial region 502 is incident on each pixel 200 at different angles on each pixel 200 of the image sensor 107 and is received by the first pupil partial region 201 and the second pupil partial region 202 of each pixel 200.

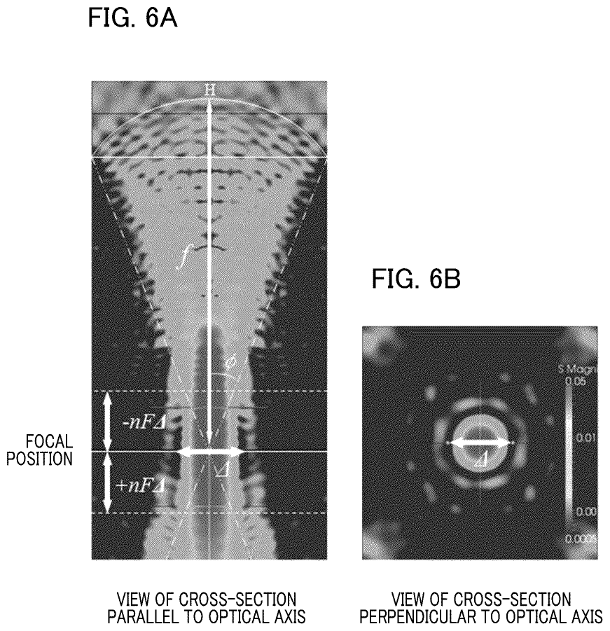

FIGS. 6A and 6B are diagrams illustrating a light intensity distribution when light is incident on the microlens 305 formed in the pixel 200. More specifically, FIG. 6A is a diagram illustrating a light intensity distribution on a cross-section parallel to an optical axis of the microlens 305 and FIG. 6B is a diagram illustrating a light intensity distribution on a cross-section perpendicular to the optical axis of the microlens 305 at a focal position of the microlens 305. The incident light is condensed at the focal position by the microlens 305. However, because of an influence of diffraction arising from a wave nature of the light, a diameter of a condensed spot is not less than a diffraction limit Δ and has a finite size. The size of the light reception surface of the photoelectric conversion unit is about 1 to 2 μm while the size of the condensed spot of the microlens 305 is about 1 μm. Therefore, the first pupil partial region 501 and the second pupil partial region 502 illustrated in FIG. 4 that have a conjugate relationship via the light reception surface of the photoelectric conversion unit and the microlens 305 are not clearly pupil-divided due to diffraction blur and form a light reception rate distribution (pupil intensity distribution) that depends on an incidence angle of the light.

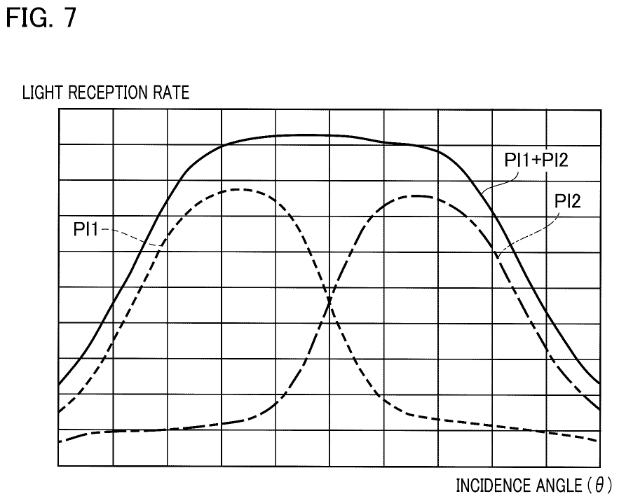

FIG. 7 is a diagram illustrating a light reception rate distribution (pupil intensity distribution) that depends on an incidence angle of light. In FIG. 7, the horizontal axis (which can be converted into pupil coordinates) represents an incident angle θ of the light and the vertical axis represents a light reception rate.

FIG. 7 illustrates a pupil intensity distribution PI1(θ) in the x direction of the first pupil partial region 501 in FIG. 4 and a pupil intensity distribution PI2(θ) in the x direction of the second pupil partial region 502 in FIG. 4. FIG. 7 further illustrates a pupil intensity distribution PI(θ)=PI1(θ)+PI2(θ) in the x direction of the pupil region 500 in which the first pupil partial region 501 and the second pupil partial region 502 in FIG. 4 are combined. As illustrated, it can be understood that a pupil is divided gradually. It can also be understood that the light reception rate of the image sensor 107 decreases when the incidence angle increases. An angle at which the light reception rate of the image sensor 107 decreases is used when an incidence angle of an imaging lens used in combination with the image sensor 107 increases. When a uniformly bright white sheet is imaged with the camera 1, there is a phenomenon in which light falls in development at a peripheral image height of captured image data, and a phenomenon in which an amount of light falls at a peripheral image height of the image sensor 107 in imaging is referred to as shading. The shading is a phenomenon occurring when a region of which a light reception rate of the image sensor 107 decreases is viewed through an exit pupil of an imaging lens.

As described above, the pupil region 500 according to the embodiment is divided into two pupil parts in the horizontal direction, but is not limited thereto. The pupil region 500 may be divided in pupil parts in the vertical direction.

In the above-described example, in the image sensor 107, the plurality of pixels 200 including the first focus detection pixel 201 and the second focus detection pixel 202 are arrayed, but the present disclosure is not limited thereto. For example, in the image sensor 107, the pixel 200, the first focus detection pixel 201, and the second focus detection pixel 202 may be separately provided, and the first focus detection pixel 201 and the second focus detection pixel 202 may be partially arrayed in parts of the array of the pixels 200.

In the embodiment, light reception signal of the first focus detection pixel 201 in each pixel 200 of the image sensor 107 is collected to generate a focus detection signal, and a light reception signal of the second focus detection pixel 202 in each pixel 200 of the image sensor 107 is collected to generate a focus detection signal and perform focus detection. The image sensor 107 generates an imaging signal (captured image) with a resolution of an effective number of pixels N for each pixel 200 by adding signals of the first focus detection pixel 201 and the second focus detection pixel 202 of each pixel.

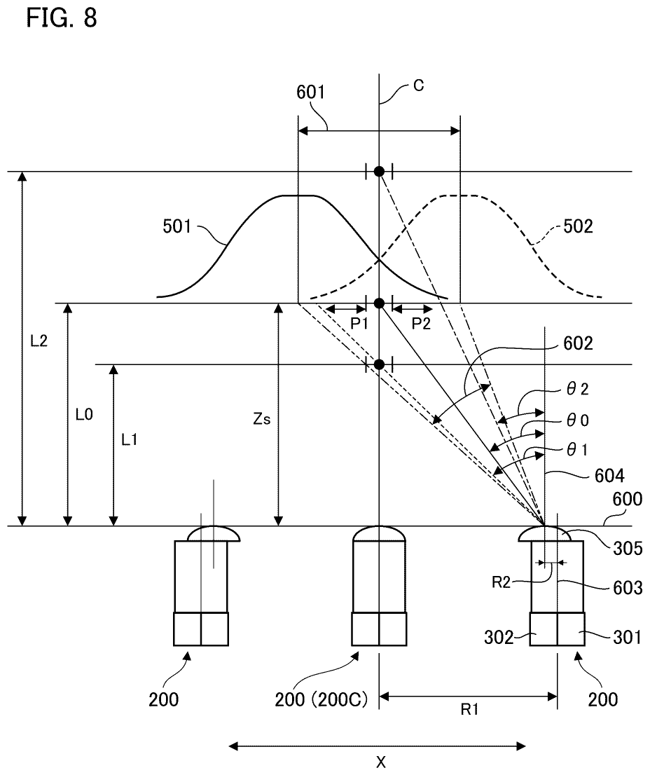

FIG. 8 is a diagram illustrating a relationship between an entrance pupil of the image sensor 107 and the exit pupil of the image forming optical system.

FIG. 8 illustrates the pixels 200 arrayed in the x direction on the surface 600 of the image sensor 107. More specifically, FIG. 8 illustrates a central pixel 200C located at the center of the image sensor 107 in the x direction, the pixel 200 located on the right side of the drawing in the x direction relative to the central pixel 200C, and the pixel 200 located on the left side of the drawing in the x direction relative to the central pixel 200C. Hereinafter, the pixel 200 located on the right side of the drawing in the x direction relative to the central pixel 200C will be described as a description target. Therefore, this pixel 200 is also referred to as a target pixel 200. The x direction illustrated in FIG. 8 is a direction in which the pupil region 500 is divided into the first pupil partial region 501 and the second pupil partial region 502. Therefore, hereinafter, the x direction is also referred to as a pupil division direction.

FIG. 8 illustrates an optical axis C of the microlens 305 in the central pixel 200C. FIG. 8 illustrates an exit pupil distance L0 in a case where the incidence pupil distance Zs of the image sensor 107 is the same as an exit pupil distance at any image height R1 in the pupil division direction of the image sensor 107, and an incidence angle θ0 on the target pixel 200 at the exit pupil distance L0. The incidence angle θ0 is an angle at which light reception intensity of the photoelectric conversion unit 301 is equal to light reception intensity of the photoelectric conversion unit 302 in the target pixel 200. Hereinafter, the angle at which the light reception intensity of the photoelectric conversion unit 301 is equal to light reception intensity of the photoelectric conversion unit 302 in the pixel 200 is also referred to as a sensor pupil angle. The sensor pupil angle of the central pixel 200C is 0°. FIG. 8 illustrates an exit pupil distance L1 in a case where the exit pupil distance is shorter than the incidence pupil distance Zs at the image height R1, and an incidence angle θ1 on the target pixel 200 at the exit pupil distance L1. FIG. 8 illustrates an exit pupil distance L2 in a case where the exit pupil distance is longer than the incidence pupil distance Zs at the image height R1, and an incidence angle θ2 on the target pixel 200 at the exit pupil distance L2. Hereinafter, an angle corresponding to the exit pupil distance is also referred to as an exit pupil angle. An exit pupil angle corresponding to the exit pupil distance L0 in the target pixel 200 is an angle θ0. An exit pupil angle corresponding to the exit pupil distance L1 in the target pixel 200 is an angle θ1. An exit pupil angle corresponding to the exit pupil distance L2 in the target pixel 200 is an angle θ2.

FIG. 8 illustrates an interval 601 between a peak position of the pupil intensity distribution of the first pupil partial region 501 and a peak position of the pupil intensity distribution of the second pupil partial region 502. FIG. 8 illustrates an angle range 602 of the interval 601 viewed from the image height R1 and a central axis 603 of a divided region of a photoelectric conversion region in the target pixel 200. The central axis 603 is a central axis in the pupil division direction between the photoelectric conversion units 301 and 302 of the target pixel 200. The central axis 603 can be ascertained as a central axis of the pupil division in the pupil division direction at the image height R1. FIG. 8 illustrates an optical axis 604 of the microlens 305 in the target pixel 200 and a deviation amount R2 between the central axis 603 and the optical axis 604.

In the embodiment, regardless of an influence of a manufacturing variation such as an alignment deviation of the microlens 305, an ideal state in which the optical axis 604 deviates toward a center image height side of the image sensor 107 relative to the central axis 603 in the target pixel 200 is assumed in description. The exit pupil distance of the image forming optical system changes depending on an image height of the image sensor 107.

The incidence pupil distance Zs is determined in accordance with a positional relationship between the central axis 603 and the optical axis 604, in other words, a relationship between the image height R1 and the deviation amount R2. More specifically, the larger the deviation amount R2 with respect to the image height R1 is, the shorter the incidence pupil distance Zs is. The smaller the deviation amount R2 with respect to the image height R1 is, the long the incidence pupil distance Zs is. When the deviation amount R2 is “0”, a principal beam angle of the pixel 200 at any image height is 0° and is parallel to a principal beam angle of the central pixel 200C, and thus the incidence pupil distance Zs becomes infinite. In the embodiment, in the pixel 200 such as the target pixel 200 located away from the center of the image sensor 107 in the x direction, it is assumed that the deviation amount R2 is greater than 0 and the optical axis 604 is located closer to the center side of the image sensor 107 than the central axis 603. In an example illustrated in FIG. 8, it is assumed that the central axis 603 passes through the center of the pixel 200 in the x direction.

At the incidence pupil distance Zs, for each pixel 200 of the image sensor 107, the first pupil partial region 501 that is a light reception region (incidence pupil) of the first focus detection pixel 201 and the second pupil partial region 502 that is a light reception region of the second focus detection pixel 202 substantially intersect the optical axis C. In the case of the exit pupil distance L0, when overlapping between the first pupil partial region 501 and the second pupil partial region 502, and the exit pupil in the image forming optical system is taken into account, a pupil deviation does not occur between the incidence pupil at the incidence distance Zs and the exit pupil in the image forming optical system. Conversely, in the case of the exit pupil distance L1, a pupil deviation of the deviation amount P1 occurs between the incidence pupil at the incidence pupil distance Zs and the exit pupil in the image forming optical system. In the case of the exit pupil distance L2, a pupil deviation of the deviation amount P2 occurs between the incidence pupil at the incidence pupil distance Zs and the exit pupil in the image forming optical system. That is, when the exit pupil distance is different from the incidence pupil distance Zs, a pupil deviation occurs between the incidence pupil at the incidence pupil distance Zs and the exit pupil in the image forming optical system.

When a deviation amount of the pupil deviation between the incidence pupil and the exit pupil in the image forming optical system increases, a baseline length is not ensured and a focus detection capability of a phase difference AF deteriorates in some cases. Accordingly, in the embodiment, the image sensor 107 is configured so that the deviation amount of the pupil deviation is suppressed for an exit pupil distance changing depending on an image height. More specifically, the image sensor 107 is configured so that the incidence pupil of the image sensor 107 is set within a predetermined threshold with respect to the exit pupil distance of the image forming optical system changing depending on the image height.

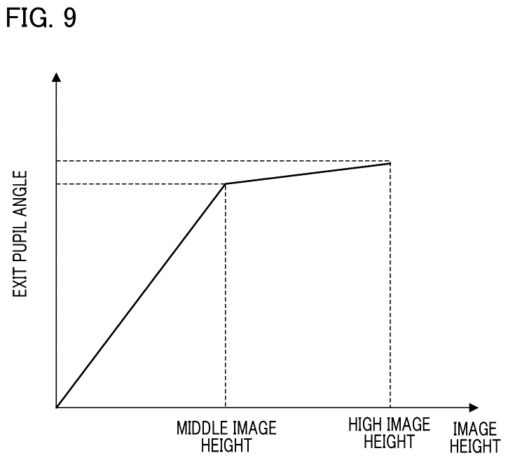

FIG. 9 is a diagram illustrating a relationship between an image height and an exit pupil angle in a specific lens. Examples of the specific lens include a lens such as a gull lens of which a change in an exit pupil angle depending an image height is large.

The specific lens will be described. In a smartphone or the like, a camera including a compact wide-angle imaging lens that has a bright f-number (F value) and a sensor size less than ½ inches is employed. In such a camera, a lens called a gull lens is employed in which an exit pupil distance is considerably different at a center image height that is an image height at a position near the center of an imaging lens and a peripheral image height that is an image height of a peripheral position located way from the center of the imaging lens. This lens is designed so that the exit pupil distance is overall short to implement miniaturization of the camera, but is designed so that an exit pupil distance of the peripheral image height becomes very long with respect to the center image height of the imaging lens in order to inhibit shading from excessively increasing. Therefore, this lens exhibits a large change in an exit pupil distance with respect to a change in the image height of the imaging lens and has an aspherical shape.

A scheme of implementing miniaturization of a camera and an improvement in image quality, there is a scheme of designing an exit pupil distance of an imaging lens that has a relationship between an image height and an exit pupil angle, as illustrated in FIG. 9. In an example illustrated in FIG. 9, while a change in exit pupil angle depending on an image height is large at an image height until a middle image height, a change in exit pupil angle depending on the image height is small at an image height from the middle image height to a high image height. Therefore, a difference in exit pupil angle is small between the middle image height and the high image height. More specifically, at the image height until the middle image height, a slope of the exit pupil angle with respect to the image height is twice or more than at the image height from the middle image height to the high image height. In this case, even when an imaging lens and an image sensor are closely spaced, the image sensor can receive light, and thus miniaturization of the camera and the improvement in quality of an image are implemented. Since a change in exit pupil angle depending on an image height from the middle image height and the high image height is small, an influence of shading (which is a phenomenon in which sensitivity of a screen deteriorates at the high image height and is also called falling of an amount of peripheral light) alleviates when the image sensor 107 is used in combination.

In the image sensor 107, when each pixel 200 is designed so that a ratio of the deviation amount R2 (see FIG. 8) to an image height is constant, the incidence pupil distance Zs is uniform on the surface of an image sensor 107. When the image sensor 107 in which the incidence pupil distance Zs is uniform is combined with an imaging lens that has the relationship of the exit pupil angle depending on the image height illustrated in FIG. 9, an image height at which a pupil deviation is large occurs. In particular, when a change in exit pupil angle (a slope of an exit pupil angle with respect to the image height) is twice or more at a boundary of a predetermined image height, occurrence of an image height at which the pupil deviation is large becomes prominent. At the image height at which the pupil deviation is large, phase difference AF performance deteriorates. In an imaging apparatus such as a smartphone, since focus detection is performed at only an open aperture value, a baseline length is easily ensured. Even when a pupil deviation occurs, a tendency of deterioration in phase difference AF performance is small. On the other hand, in a moving image recording apparatus or the like used for movie filming, since highly accurate focus detection at any image height in a small diaphragm is required, it is necessary to inhibit deterioration in phase difference AF performance.

Accordingly, in the embodiment, each pixel 200 of the image sensor 107 is designed so that an incidence pupil distance changes depending on an image height in accordance with a change in exit pupil angle of the imaging lens depending on the image height in the pupil division direction. More specifically, each pixel 200 of the image sensor 107 is designed so that an exit pupil distance at any image height is the same as the incidence pupil distance. In this way, even when an imaging lens in which a change in exit pupil angle depending on an image height is large is used, an image sensor that reduces an influence of pupil deviation and performs focus detection with high accuracy at any image height is implemented.

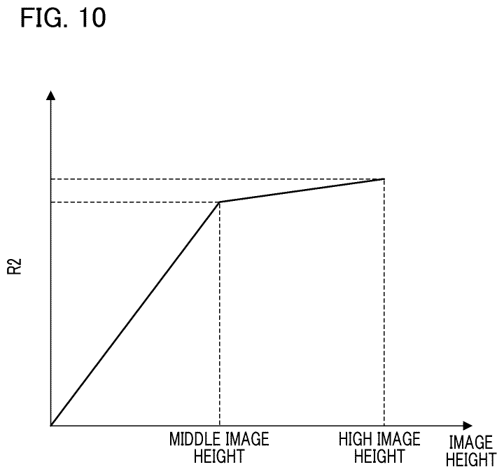

FIG. 10 is a diagram illustrating a relationship between an image height and the deviation amount R2 when an imaging lens having the relationship between the image height and the exit pupil angle illustrated in FIG. 9 is used and when an incidence pupil distance is the same as an exit pupil distance.

In the embodiment, the deviation amount R2 is determined depending on an image height in accordance with a change in exit pupil angle depending on the height image illustrated in FIG. 9. More specifically, each pixel 200 of the image sensor 107 is designed so that a slope of the exit pupil angle with respect to the image height and a slope of the deviation amount R2 with respect to the image height are equal at each image height. Therefore, as illustrated in FIG. 10, while a change in deviation amount R2 depending on an image height is large at an image height until a middle image height, a change in deviation amount R2 depending on the image height is small at an image height from the middle image height to a high image height. Therefore, a difference in deviation amount R2 is small between the middle image height and the high image height. In this way, an incidence pupil distance is determined so that an exit pupil distance is equal at any image height.

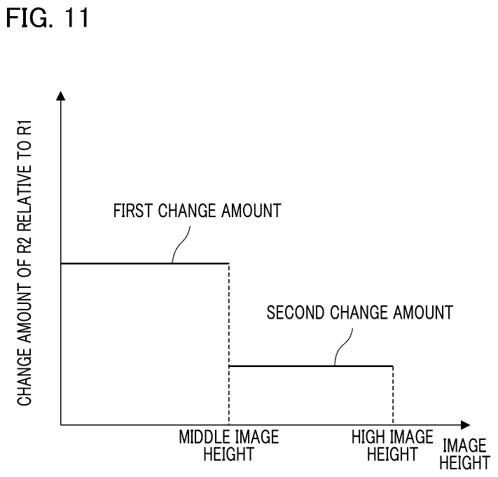

FIG. 11 is a diagram illustrating a relationship between an image height of the image sensor 107 and a change amount of the deviation amount R2 relative to any image height R1. The change amount of the deviation amount R2 relative to any image height R1 is obtained by differentiating a slope of the deviation amount R2 illustrated in FIG. 10 with respect to the image height.

As illustrated in FIG. 11, at an image height until the middle image height, a change amount of the deviation amount R2 relative to any image height R1 is constant and is a first change amount. At an image height from the middle image height to the high image height, the change amount of the deviation amount R2 relative to any image height R1 is constant and is a second change amount less than the first change amount. In the embodiment, as illustrated in FIG. 10, the change amount of the deviation amount R2 relative to the image height is greater at the image height until the middle image height than at the image height from the middle image height to the high image height. Therefore, the change amount of the deviation amount R2 relative to any image R1 is greater at the image height until the middle image height than at the image height from the middle image height to the high image height.

In the embodiment, to array many pixels 200 in the image sensor 107, the photoelectric conversion units are divided and arrayed in the x direction in the image sensor 107. Here, when the horizontal direction (x direction) in which the number of arrayed pixels 200 is large is referred to as a longitudinal direction of the image sensor 107, the longitudinal direction becomes a signal reading direction of the image sensor 107 in order to increase the number of signals to be transferred for each transmission, in other words, to increase signal transfer efficiency. In the image sensor 107 according to the embodiment, since the photoelectric conversion of each pixel 200 is divided into the photoelectric conversion units 301 and 302, the number of read signals is twice than in the image sensor 107 in which the photoelectric conversion unit is not divided. Accordingly, in the embodiment, the longitudinal direction of the image sensor 107 is matched with the signal reading direction. In other words, the pupil division direction of the image sensor 107 is matched with the longitudinal direction of the image sensor 107.

In the embodiment, in a transverse direction of the image sensor 107, the pixels 200 are arrayed so that the microlens 305 are formed at an equal pitch.

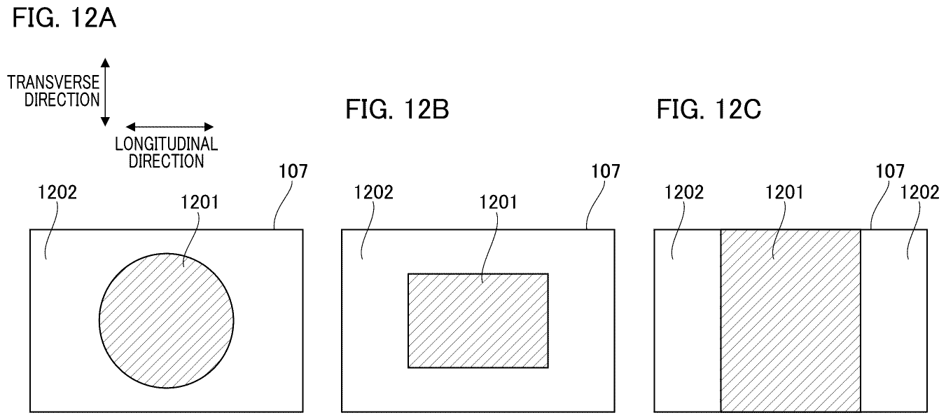

FIGS. 12A to 12C are diagrams illustrating a relationship of a change amount of the deviation amount R2 relative to the image height R1 for each pixel 200 of the image sensor 107.

As illustrated in FIGS. 12A to 12C, in the image sensor 107, the first region 1201 where a change amount of R2 relative to the image height R1 is the first change amount (see FIG. 11) and the second region 1202 where a change amount of R2 relative to the image height R1 is the second change amount are determined. This means that the change amount of R2 relative to the image height R1 in the pixel 200 located in the first region 1201 is the first change amount, and the change amount of R2 relative to the image height R1 in the pixel 200 located in the second region 1202 is the second change amount. As illustrated in FIGS. 12A to 12C, in the image sensor 107, either the first region 1201 or the second region 1202 is determined in accordance with a position in the longitudinal direction and the transverse direction of the image sensor 107.

As a relationship between the first region 1201 and the second region 1202 in the image sensor 107, there is the relationship illustrated in FIG. 12A. In the example illustrated in FIG. 12A, a range of a radius determined in advance from the center of the image sensor 107 is determined as the first region 1201, and a region outside of the first region 1201 is determined as the second region 1202. In other words, in the example illustrated in FIG. 12A, the first region 1201 and the second region 1202 are determined in a radial direction from the center of the image sensor 107 according to the center side or the outside of the image sensor 107 relative to the middle image height. In the configuration illustrated in FIG. 12A, the first region 1201 and the second region 1202 can be easily adapted to an imaging lens in which an exit pupil angle is designed to be rotationally symmetric with respect to the optical axis.

As a relationship between the first region 1201 and the second region 1202 in the image sensor 107, there is the relationship illustrated in FIG. 12B. In the example illustrated in FIG. 12B, a rectangular region of which a center matches the center of the image sensor 107 is determined as the first region 1201, and a region outside of the first region 1201 is determined as the second region 1202. The first region 1201 extends in the longitudinal direction of the image sensor 107 rather than the transverse direction of the image sensor 107. The second region 1202 is provided on both outer sides of the first region 1201 in the longitudinal direction and both outer sides of the first region 1201 in the transverse direction. Additionally, in the example illustrated in FIG. 12B, the middle image height in the longitudinal direction of the image sensor 107 and the middle image height in the transverse direction of the image sensor 107 are determined as boundaries. The first region 1201 and the second region 1202 are determined depending on whether the region is closer to the center side or the outer side of the image sensor 107 than the boundary. The middle image height in the transverse direction of the image sensor 107 is closer to the center of the image sensor 107 than the middle image height in the longitudinal direction of the image sensor 107. In the configuration illustrated in FIG. 12B, the image sensor 107 is designed more easily than in the configuration illustrated in FIG. 12A to the degree that the pixels 200 of the image sensor 107 are easily arrayed.

As a relationship between the first region 1201 and the second region 1202 in the image sensor 107, there is the relationship illustrated in FIG. 12C. In the example illustrated in FIG. 12C, a rectangular region of which a center matches the center of the image sensor 107 is determined as the first region 1201, and a region outside of the first region 1201 is determined as the second region 1202. The first region 1201 extends in the transverse direction of the image sensor 107 rather than the longitudinal direction of the image sensor 107. More specifically, the first region 1201 is provided up to distal ends of both sides in the longitudinal direction of the image sensor 107. The second region 1202 is provided on both outer sides of the first region 1201 in the longitudinal direction and is not provided both outer sides of the first region 1201 in the transverse direction. In the configuration illustrated in FIG. 12C, the incidence pupil distance Zs is constant regardless of the image height in the transverse direction of the image sensor 107. The high image height is shorter in the transverse direction of the image sensor 107 different from the pupil division direction than in the longitudinal direction, and accuracy of the focus detection is less likely to be affected by the image height in the transverse direction. Therefore, even in the configuration illustrated in FIG. 12C, the accuracy of the focus detection is ensured. In the configuration illustrated in FIG. 12C, the image sensor 107 is more easily designed than in the configuration illustrated in FIG. 12B.

A variation may occur in the individual image sensor 107 or imaging lens due to a manufacturing influence. Based on this point, when the incidence pupil distance Zs is set so that the exit pupil angle of the imaging lens is included in the angle range 602 (see FIG. 8), the image sensor capable of executing focus detection with high accuracy at any image height despite occurrence of a variation in the individual image sensor 107 or imaging lens is implemented.

Next, a modified example of an image sensor 107 will be described.

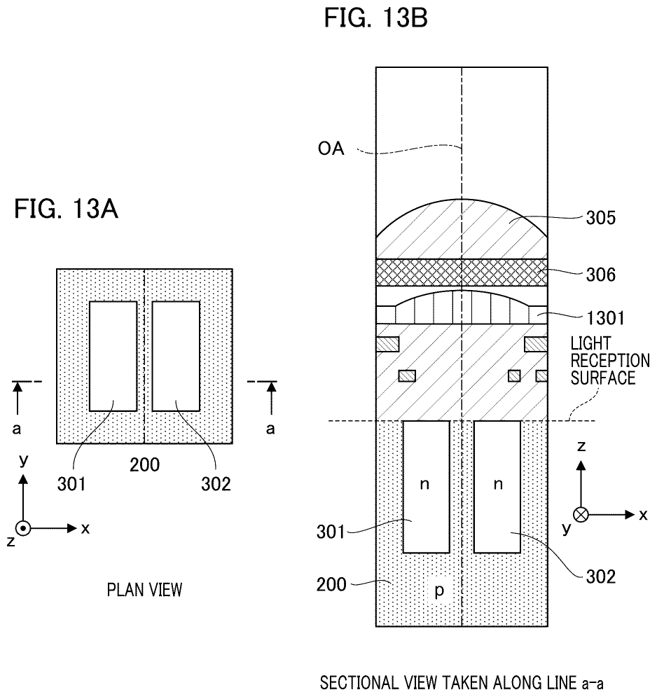

FIG. 13A is a plan view when a pixel 200 in the image sensor 107 is viewed from a light reception plane side (+z side) of the image sensor 107 and FIG. 13B is a sectional view taken along the line a-a when the pixel 200 illustrated in FIG. 13A is viewed from on the −y side according to the modified example.

Different configurations of the image sensor 107 according to the modified example from the configurations of the above-described image sensor 107 will be described, and the same configurations as the configurations of the above-described image sensor 107 will not be described.

As illustrated in FIG. 13B, in the pixel 200 of the image sensor 107 according to the modified example, an in-layer lens 1301 is provided near the microlens 305 below the microlens 305.

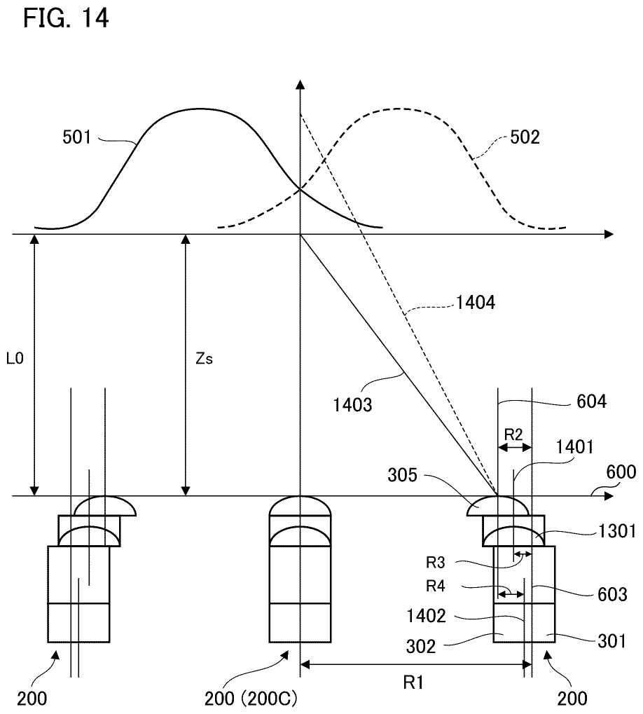

FIG. 14 is a diagram illustrating a relationship between an entrance pupil of the image sensor 107 and an exit pupil of an image forming optical system according to the modified example.

FIG. 14 illustrates an optical axis 1401 of the in-layer lens 1301 in the target pixel 200, a central axis 1402 of the pixel 200 at the image height R1, and a principal beam 1403 serving as a focus detection pixel in the pixel 200 at the image height R1. FIG. 14 illustrates a principal beam 1404 serving as an imaging pixel in the pixel 200 at the image height R1. FIG. 14 illustrates a deviation amount R3 between the central axis 603 of a divided region of the photoelectric conversion region in the target pixel 200 and the optical axis 1401, and a deviation amount R4 between the optical axis 604 of the microlens 305 in the target pixel 200 and the central axis 1402.

As illustrated in FIG. 14, in the pixel 200 of the image sensor 107 according to the modified example, the central axis 603 deviates from the central axis 1402 of the pixel 200 in the pupil division direction. In other words, in the example illustrated in FIG. 14, a pitch of pupil division is greater than a pitch of the pixel 200 with respect to a change in image height of the image sensor 107. In the modified example, in the pixel 200 except for the central pixel 200C in the image sensor 107, the central axis 603 deviates from the central axis 1402 in the pupil division direction. Conversely, in the central pixel 200C, the the central axis 603 matches the central axis 1402 in the pupil division direction. The principal beam 1403 serving the focus detection pixel in the pixel 200 at the image height R1 is determined in accordance with a positional relationship between the central axis 603 and the optical axis 604. The principal beam 1404 serving as the imaging pixel in the pixel 200 at the image height R1 is determined in accordance with a positional relationship between the central axis 1402 and the optical axis 604.

As illustrated in FIG. 14, when the central axis 603 in the target pixel 200 deviates from the central axis 1402 in the pupil division direction, angles of the principal beam 1403 serving as the focus detection pixel and the principal beam 1404 serving as the imaging pixel to the optical axis 604 can be changed at any image height. In the illustrated example, since the deviation amount R2 is less than the deviation amount R4 with respect to the optical axis 604 of the microlens 305, the angle of the principal beam 1403 serving as the focus detection pixel to the optical axis 604 is greater than that of the principal beam 1404 serving as the imaging pixel.

When the angles of the principal beam 1403 serving as the focus detection pixel and the principal beam 1404 serving as the imaging pixel to the optical axis 604 are changed, the image sensor 107 is easily designed so that the incidence pupil distance Zs and the shading characteristics of imaging in the the image sensor 107 are independent. In the image sensor 107 illustrated in FIG. 8, in order to change the incidence pupil distance Zs in accordance with the image height, it is necessary to design each pixel 200 so that a pitch of the microlens 305 is changed in accordance with the image height.

On the other hand, in the image sensor 107 illustrated in FIG. 14, each pixel 200 is designed so that the pitch of the central axis 603 is changed in accordance with the image height. In this way, even when the pitch of the microlens 305 is uniform regardless of the image height, the relationship between the image height and the deviation amount R2 illustrated in FIG. 10 and the relationship between the image height and the deviation amount R2 from the image height R1 illustrated in FIG. 11 are implemented. That is, a change in the incidence pupil distance Zs in accordance with the image height is implemented. As in the image sensor 107 illustrated in FIG. 14, when the pitch of the microlens 305 is uniform regardless of the image height, shading unevenness of the image sensor 107 is less likely to occur. The shading unevenness is a phenomenon in which a change in shading becomes discontinuous depending on the image height even when a subject with uniform luminance is imaged. The shading unevenness easily occurs when the pitch of the microlens 305 changes depending on the image height. Here, even when the angles of the principal beam 1403 serving as the focus detection pixel and the principal beam 1404 serving as the imaging pixel to the optical axis 604 are changed, there is limitation. Accordingly, even when the angles of the principal beam 1403 serving as the focus detection pixel and the principal beam 1404 serving as the imaging pixel to the optical axis 604 are changed, each pixel 200 may be designed so that the pitch of the microlens 305 changes depending on the image height.

Next, a pitch of the in-layer lens 1301 will be described.

The in-layer lens 1301 inhibits deterioration in sensitivity caused due to miniaturization of the pixel 200. The angle of the principal beam 1403 serving as the focus detection pixel to the optical axis 604 is determined by the microlens 305. Therefore, while the in-layer lens 1301 assists a light condensing capability of an optical system of the pixel 200, an influence on adjustment of the angle of the principal beam 1403 serving as the focus detection pixel to the optical axis 604 is less than that of the microlens 305. When the pitch of the in-layer lens 1301 is changed depending on the image height of the image sensor 107, this change may be a cause of the shading unevenness. Therefore, the pitch of the in-layer lens 1301 may be uniform regardless of the image height.

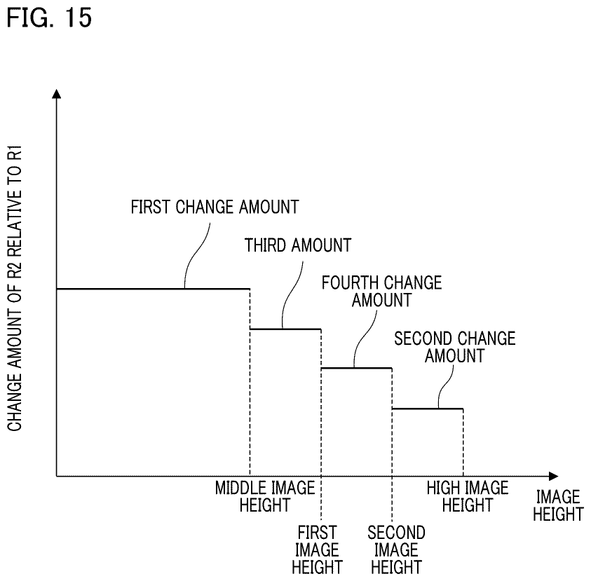

FIG. 15 is a diagram illustrating a relationship between an image height of the image sensor 107 and a change amount of the deviation amount R2 relative to any image height according to a modified example.

The relationship between the image height of the image sensor 107 and the change amount of the deviation amount R2 relative to any image height R1 is not limited to the example illustrated in FIG. 11.

As illustrated in FIG. 15, at the image height until the middle image height, the change amount of the deviation amount R2 relative to any image height R1 is constant and is a first change amount. At an image height from the middle image height to a first image height, the change amount of the deviation amount R2 relative to any image height R1 is constant and is a third change amount less than the first change amount. At an image height from the first image height to a second image height, a change amount of the deviation amount R2 relative to any image height R1 is constant and is a fourth change amount less than the third change amount. At an image height from the second image height to the high image height, the change amount of the deviation amount R2 relative to any image height R1 is constant and is a second change amount less than the fourth change amount.

In this way, when the number of stages in which the change amount of the deviation amount R2 relative to any image height R1 is different is greater than in the configuration illustrated in FIG. 11 and a difference in the change amount in continuous stages is less than in the configuration illustrated in FIG. 11, a width of the change in incidence pupil distance Zs depending on the image height decreases. In this case, compared with the configuration illustrated in FIG. 11, the influence of the shading unevenness is reduced.

The number of stages in which the change amount of the deviation amount R2 relative to any image height R1 differs may be any number. For example, stages in which the change amount of the deviation amount R2 relative to any image height R1 differs may be provided to the degree that the change amount of the deviation amount R2 relative to any image height R1 approximates a continuous change at each stage.

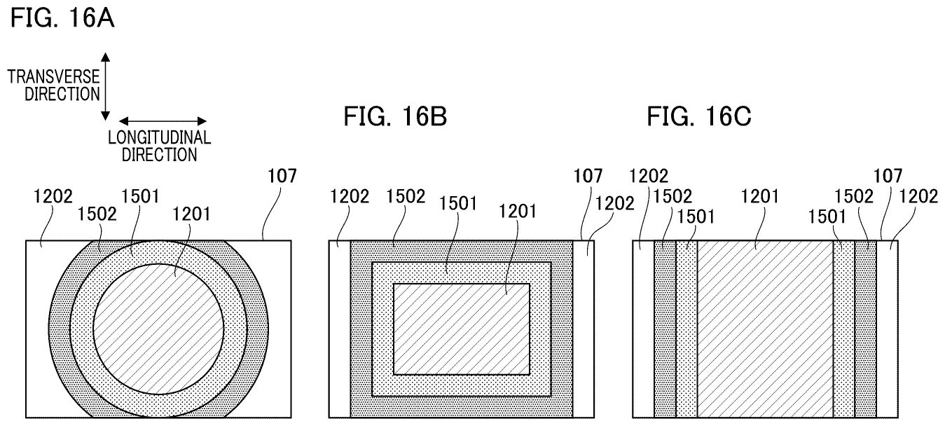

FIGS. 16A to 16C are diagrams illustrating a relationship of a change amount of the deviation amount R2 relative to the image height R1 in each pixel 200 of the image sensor 107 to correspond to the configuration of FIG. 15.

As illustrated in FIGS. 16A to 16C, in the image sensor 107, as described above, the first region 1201 (see FIGS. 12A to 12C) and the second region 1202 are determined. In the image sensor 107, a third region 1501 where the change amount of R2 relative to the image height R1 is the third change amount (see FIG. 15) and a fourth region 1502 where the change amount of R2 relative to the image height R1 is the fourth change amount are determined. This means that the change amount of R2 relative to the image height R1 in the pixel 200 located in the third region 1501 is the third change amount and the change amount of R2 relative to the image height R1 in the pixel 200 located in the fourth region 1502 is the fourth change amount. As illustrated in FIGS. 16A to 16C, in the image sensor 107, one of the first region 1201, the second region 1202, the third region 1501, and the fourth region 1502 is determined in accordance with a position in the longitudinal direction and the transverse direction of the image sensor 107.

The first region 1201 illustrated in FIG. 16A is a region that is the same as the first region 1201 illustrated in FIG. 12A. The first region 1201 illustrated in FIG. 16B is a region that is the same as the first region 1201 illustrated in FIG. 12B. The first region 1201 illustrated in FIG. 16C is a region that is the same as the first region 1201 illustrated in FIG. 12C.

As a relationship among the first region 1201, the third region 1501, the fourth region 1502, and the second region 1202 in the image sensor 107, there is a relationship illustrated in FIG. 16A. In the example illustrated in FIG. 16A, a range of a radius greater than that of the first region 1201 from the center of the image sensor 107 is determined as the third region 1501, and a range of a radius greater than that of the third region 1501 from the center of the image sensor 107 is determined as the fourth region 1502. Further, a region outside of the fourth region 1502 is determined as the second region 1202.

As a relationship among the first region 1201, the third region 1501, the fourth region 1502, and the second region 1202 in the image sensor 107, there is a relationship illustrated in FIG. 16B. In the example illustrated in FIG. 16B, the third region 1501 is provided on both outer sides of the first region 1201 in the longitudinal direction and both outer sides of the first region 1201 in the transverse direction. The fourth region 1502 is provided on both outer sides of the third region 1501 in the longitudinal direction and both outer sides of the third region 1501 in the transverse direction. The fourth region 1501 is provided up to distal ends of both sides in the transverse direction of the image sensor 107. The second region 1202 is provided on both outer sides of the fourth region 1502 in the longitudinal direction.

As a relationship among the first region 1201, the third region 1501, the fourth region 1502, and the second region 1202 in the image sensor 107, there is a relationship illustrated in FIG. 16C. In the example illustrated in FIG. 16C, the third region 1501 is provided on both outer sides of the first region 1201 in the longitudinal direction, and the fourth region 1502 is provided on both outer sides of the third region 1501 in the longitudinal direction. The second region 1202 is provided on both outer sides of the fourth region 1502 in the longitudinal direction. The third region 1501, the fourth region 1502, and the second region 1202 are all provided up to distal ends of both sides in the longitudinal direction of the image sensor 107.

As described above, the image sensor 107 according to the embodiment is the image sensor 107 having the pixels 200 in which the photoelectric conversion region divided into the plurality of regions in the first direction are arrayed in the 2-dimensional form, and the longitudinal direction of the image sensor 107 matches the first direction. In the first direction, a change amount of the deviation amount R2 between the optical axis 604 of the microlens 305 included in the pixel 200 and the center of the divided region of the photoelectric conversion region with respect to a change in image height that is a distance from the center of the image sensor 107 is a first change amount on the center side relative to a first predetermined image height. As the center of the divided region of the photoelectric conversion region, there is the central axis 603. As the first predetermined image height, there is the middle image height in the longitudinal direction of the image sensor 107. In the first direction, a change amount of the deviation amount R2 with respect to a change in image height that is a distance from the center of the image sensor 107 is a second change amount on the outer side of the first predetermined image height, and the first change amount is greater than the second change amount.

In this case, it is possible to provide an image sensor 107 that performs focus detection with high accuracy at any image height even when the image sensor is used in combination with an imaging lens having a large change in an exit pupil distance in accordance with an image height.

In the embodiment, the microlenses 305 are formed at an equal pitch in the transverse direction of the image sensor 107.

In this case, compared with a configuration in which the microlenses 305 are formed at different pitches in the transverse direction of the image sensor 107, design of the image sensor 107 is simpler.

In the embodiment, in the pixel 200 located at a position deviating from the center of the image sensor 107 in one direction, the position of the center of the divided region of the photoelectric conversion region in one direction matches the center of the pixel 200 (see FIG. 8). As the pixel 200 located at a position deviating from the center of the image sensor 107 in one direction, there is the pixel 200 such as the target pixel 200 different from the central pixel 200C (see FIG. 8).

In this case, compared with a configuration in which the position of the center of the divided region of the photoelectric conversion region in one direction does not match the center of the pixel 200, design of the pixel 200 is simpler.

In the embodiment, the center of the divided region of the photoelectric conversion region in the pixel 200 located at a position deviating from the center of the image sensor 107 in one direction is located on a side opposite to the center side of the image sensor 107 relative to the center of the pixel 200 in one direction (see FIG. 14).

In this case, at any image height, the angles of the principal beam 1403 serving as the focus detection pixel and the principal beam 1404 serving as the imaging pixel to the optical axis 604 can be changed.

In the embodiment, in a radial direction of the image sensor 107, a change amount of the deviation amount R2 with respect to a change in image height that is a distance from the center of the image sensor 107 is a first change amount on the center side relative to the first predetermined image height and is a second change amount on the outer side relative to the first predetermined image height.

In this case, it is easy to cause a boundary of the change amount to correspond to an imaging lens in which an exit pupil angle is designed to be rotationally symmetric with respect to the optical axis.

In the embodiment, a change amount of the deviation amount R2 with respect to a change in image height that is a distance from the center of the image sensor 107 in the transverse direction of the image sensor 107 is a first change amount on the center side relative to a second predetermined image height and a second change amount on the outer side relative to the second predetermined image height. The second predetermined image height is on a center side of the image sensor 107 relative to the first predetermined image height (see FIGS. 12B and 16B).

In this case, compared with a configuration in which the change amount is determined in accordance with the image height in the radial direction of the image sensor 107, array of the pixels 200 in the image sensor 107 is easier.

In the embodiment, a change amount of the deviation amount R2 with respect to a change in image height that is a distance from the center of the image sensor 107 in the transverse direction of the image sensor 107 is a first change amount regardless of the image height (see FIGS. 12C and 16C).

In this case, while accuracy of focus detection is ensured, array of the pixels 200 in the image sensor 107 is easier.

In the embodiment, the camera 1 further includes an imaging lens in which a slope of an exit pupil angle with respect to an image height is twice or more (see FIG. 9) at an image height of the center side relative to the first predetermined image height, compared with an image height on the outer side relative to the first predetermined image height. As the imaging lens, for example, there is a gull lens.

In this case, even in the configuration of the camera 1 in which occurrence of an image height at which pupil deviation is large becomes prominent, the camera 1 that performs focus detection with high accuracy at any image height is provided.

In the embodiment, the exit pupil angle and the sensor pupil angle have been described. Here, in the image sensor 107, a difference between the exit pupil angle and the sensor pupil angle may be within a predetermined threshold.

In the embodiment, the pixels 200 that are arrayed in the x direction in the image sensor 107 have been described. Here, each pixel 200 may be designed to be symmetric in the x direction (bilateral symmetric in FIG. 8) centering on the central pixel 200C (see FIG. 8).

In the embodiment, the central axis 603 of the divided region of the photoelectric conversion region in the pixel 200 does not match the center of the pixel 200 in the longitudinal direction of the image sensor 107, as described above (see FIG. 14). In this case, each lens may be generated by reducing (shrinking) a microlens array in which a central position of each microlens 305 matches a central position of the photoelectric conversion unit of each pixel 200 in the horizontal and vertical directions at a constant ratio.

The in-layer lens 1301 may be provided in the image sensor 107, as described above. Here, in the longitudinal direction of the image sensor 107, a change amount of the deviation amount R3 with respect to a change in image height may be determined. More specifically, this change amount may be the first change amount on the central axis relative to a third predetermined image height and may be the second change amount on the outer side relative to the third predetermined image height. In this case, the first predetermined image height may differ from the third predetermined image height.

Each lens may be generated by reducing (shrinking) a microlens array in which a central position of each microlens 305 matches a central position of the photoelectric conversion unit of each pixel 200 in the horizontal and vertical directions at a constant ratio.

In the embodiment, the x direction illustrated in FIG. 2 is the longitudinal direction of the image sensor 107 and the y direction is the transverse direction of the image sensor 107, as described above, but the present disclosure is not limited thereto.

In the image sensor 107, a length in the x direction may match a length in the y direction.

The present disclosure can also be embodied in a process of supplying a program that implement one or more functions of the embodiment to the camera 1 via a network or a storage medium and causing one or more processors of a computer for the camera 1 to read and execute the program. The present disclosure can also be embodied by a circuit (for example, an ASIC) that implements one or more functions.

An embodiment of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment, and by a method performed by the computer of the system or apparatus by, for example, reading out and executing the computer executable instructions from the storage medium to perform the functions of one or more of the above-described embodiment and/or controlling the one or more circuits to perform the functions of one or more of the above-described embodiment. The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD) TM), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

According to the present disclosure, it is possible to provide an image sensor that performs focus detection with high accuracy at any image height even when the image sensor is used in combination with an imaging lens having a large change in an exit pupil distance in accordance with an image height.

This application claims the benefit of Japanese Patent Application No. 2024-198225, filed Nov. 13, 2024, which is hereby incorporated by reference wherein in its entirety.

1. An image sensor comprising:
pixels that each have a photoelectric conversion region divided into a plurality of regions in a first direction and are arrayed in a 2-dimensional form,
wherein a longitudinal direction of the image sensor matches the first direction,
wherein, in the first direction, a change amount of a deviation amount between an optical axis of a microlens included in the pixel and a center of a divided region of the photoelectric conversion region, relative to a change in an image height that is a distance from a center of the image sensor is a first change amount on a center side relative to a first predetermined image height and is a second change amount on an outer side relative to the first predetermined image height, and
wherein the first change amount is greater than the second change amount.

2. The image sensor according to claim 1, wherein the microlenses are formed at an equal pitch in a transverse direction of the image sensor.

3. The image sensor according to claim 1, wherein, in the pixel located at a deviated position in the first direction from the center of the image sensor, a center of the divided region of the photoelectric conversion region matches a center of the pixel at the position in the first direction.

4. The image sensor according to claim 1, wherein, in the pixel located at a deviated position in the first direction from the center of the image sensor, a center of the divided region of the photoelectric conversion region is located closer to a side opposite to a center side of the image sensor than the center of the pixel in the first direction.

5. The image sensor according to claim 1, wherein, in a radial direction of the image sensor, the change amount is the first change amount on the center side relative to the first predetermined image height and is the second change amount on an outer side relative to the first predetermined image height.

6. The image sensor according to claim 1,
wherein, in a transverse direction of the image sensor, the change amount is the first change amount on the center side relative to a second predetermined image height and is the second change amount on an outer side relative to the second predetermined image height, and
wherein the second predetermined image height is on a center side of the image sensor relative to the first predetermined image height.

7. The image sensor according to claim 1, wherein, in a transverse direction of the image sensor, the change amount is the first change amount regardless of the image height.

8. An imaging apparatus comprising:
an image sensor including pixels that each have a photoelectric conversion region divided into a plurality of regions in a first direction and are arrayed in a 2-dimensional form; and
a processing unit configured to process a signal output from the image sensor,
wherein a longitudinal direction of the image sensor matches the first direction,
wherein, in the first direction, a change amount of a deviation amount between an optical axis of a microlens included in the pixel and a center of a divided region of the photoelectric conversion region, relative to a change in an image height that is a distance from a center of the image sensor is a first change amount on a center side relative to a first predetermined image height and is a second change amount on an outer side relative to the first predetermined image height, and
wherein the first change amount is greater than the second change amount.

9. The imaging apparatus according to claim 8, further comprising:
an imaging lens in which, at an image height of a center side relative to the first predetermined image height, a slope of an exit pupil angle with respect to an image height is two times or more than an image height of an outer side relative to the first predetermined image height.
